(19) United States
(12) Patent Application Publication
(10) Pub. No.: US 2005/0180475 A1
(43) Pub. Date: Aug. 18, 2005

(54) Semiconductor laser device

(75) Inventors: Kyoung-ho Ha, Seoul (KR); Joon-seop Kwak, Gyeonggi-do (KR); Sung-nam Lee, Gyeonggi-do (KR); Jung-hye Chae, Seoul (KR)

Correspondence Address: BURNS DOANE SWECKER & MATHIS L L P, POST OFFICE BOX 1404, ALEXANDRIA, VA, 22313-1404, US

(73) Assignee: Samsung Electronics Co., Ltd., Gyeonggi-do (KR)

(21) Appl. No.: 11/061,541

(22) Filed: Feb. 18, 2005

(30) Foreign Application Priority Data
Feb. 18, 2004 (KR) 10-2004-0010661

(51) Int. Cl. H01S 5/00

(52) U.S. Cl. 372/44.01

(57) ABSTRACT

The provided semiconductor laser device includes a substrate, an active layer, a first cladding layer located between the active layer and the substrate, a second cladding layer located on the active layer, and a first electrode layer including a metal waveguide layer, which is formed of a metal having a smaller refractive index than the second cladding layer, and formed on the second cladding layer, wherein the first electrode layer is formed to operate as a waveguide.

### BACKGROUND OF THE INVENTION

Priority is claimed to Korean Patent Application No. 10-2004-0010661, filed on Feb. 18, 2004, in the Korean Intellectual Property Office, the disclosure of which is incorporated herein in its entirety by reference.

1. Field of the Invention

The present invention relates to a semiconductor laser device and a method of manufacturing the same, and more particularly, to a semiconductor laser device for increasing an optical confinement factor (OCF) and a method of manufacturing the same.

2. Description of the Related Art

A semiconductor laser device using GaN attracts attention as a light source of an optical system for recording and/or reproducing data on and/or from a high density optical information storage medium succeeding a DVD, for example, a blu-ray disc (BD) and an advanced optical disc (AOD).

The semiconductor laser device should preserve a long lifespan under the conditions of a high temperature and a high output in order to be used as the light source of the optical system. Thus, operation current and voltage of the semiconductor laser device should be low. In addition, in order to reduce the operation current and voltage of the semiconductor laser device, a high optical gain for input charges should be secured. Accordingly, a large amount of optical fields should be distributed on an active layer of the semiconductor laser device, because a laser oscillation is generally generated by obtaining a gain from currents that are input from the outside and the laser oscillation requires a small amount of currents when large portions of an oscillation mode and a gain area are overlapped.

According to the operation principle of a semiconductor laser, a light emission occurs by combining electrons and holes, and photons generated are fed-back through mirror surfaces located at both sides of a laser resonator so that lasing occurs. Thus, electrical and optical confinements to the active area should be generated at the same time.

When an OCF is increased, a gain of obtaining an optical mode at the same input current is increased, resulting in the decrease in the oscillation critical current of the semiconductor laser. In addition, the lowered critical current lowers the operation current, resulting in the increase in the lifespan of the semiconductor laser.

The OCF, which is induced by the distribution of a refractive index and the difference of sizes, is related to the composition and the thickness of a material.

In a conventional method of increasing an OCF, the thickness of a cladding layer is increased or the amount of Al in the cladding layer is increased to increase the difference of refractive indexes of an active layer and the cladding layer.

However, when the amount of Al in an AlGaN-based cladding layer is increased to reduce the refractive index of the cladding layer, cracks occur during an epitaxial growth, or the thickness of the cladding layer cannot be increased over a predetermined thickness. When the thickness of the cladding layer with a small amount of Al is increased, the perpendicular resistance of a semiconductor laser device is rapidly increased, thus a driving voltage. In otherwords, an operation current is increased. As a result, a growth temperature is increased, resulting in the deterioration of an active layer during a growth process.

As described above, in the cladding layer with a large amount of Al and a large thickness, problems occur including the generation of cracks and the increase of an operation voltage. Furthermore, the method of increasing the amount of Al or the thickness of the cladding layer increases the asymmetry of an optical mode, resulting in the increase in the asymmetry of a far field pattern to reduce a signal-to-noise ratio (SNR).

### SUMMARY OF THE INVENTION

The present invention provides a semiconductor laser device with a sufficient optical confinement effect without increasing the composition of Al or the thickness of a cladding layer.

According to an aspect of the present invention, there is provided a semiconductor laser device comprising a substrate, an active layer, a first cladding layer located between the active layer and the substrate, a second cladding layer located on a side of the active layer opposite to the first cladding layer, and a first electrode layer including a metal waveguide layer, which is formed of a metal having a smaller refractive index than the second cladding layer, and formed on the second cladding layer on a side opposite to the active layer, wherein the first electrode layer is formed to operate as a waveguide.

The first electrode layer may comprise the metal waveguide layer and a metal contact layer located between the second cladding layer and the metal waveguide layer.

Here, the metal waveguide layer may be formed of at least any one selected from Li, Na, K, Cr, Co, Pd, Cu, Au, Ir, Ni, Pt, Rh, and Ag.

In other case, the first electrode layer may comprise the metal waveguide layer only, which operates as a contact layer and a waveguide.

Here, the metal waveguide layer may be formed of at least any one selected from Pd, Ag, Rh, Cu, and Ni.

The semiconductor laser device may further comprise a first waveguide layer and a second waveguide layer between the first cladding layer and the active layer and the active layer and the second cladding layer, respectively.

The semiconductor laser device may further comprise an ohmic layer between the second cladding layer and the first electrode layer.

The semiconductor laser device may further comprise a ridge, wherein the ridge is formed by etching to any thickness of the second cladding layer or the second cladding layer in the remainder portion except for a portion corresponding to the ridge.

Here, an ohmic contact layer may be formed between the portion of the second cladding layer corresponding to the ridge and the first electrode layer.

The semiconductor laser device may further comprise a protective layer covering the surface of the second cladding layer that is exposed by etching to form the ridge and the sidewalls of the ridge.

A buffer layer may be formed between the substrate and the first cladding layer.

A step structure may be formed on the buffer layer, and a second electrode layer may be formed on the buffer layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view illustrating the stack structure of a semiconductor laser device according to a first embodiment of the present invention;

FIG. 2 is a sectional view illustrating the stack structure of a semiconductor laser device according to a second embodiment of the present invention;

FIG. 3 is a graph illustrating an absorption coefficient and a refractive index of gold (Au) according to photon energy;

FIG. 4 illustrates a mode profile in the case where a p-type cladding layer is formed to a thickness of 0.5 μm by using AlGaN/GaN supper lattice and an electrode layer is formed to a thickness of 1,500 Å by using Pd thereon as in a conventional semiconductor laser device; and

FIG. 5 illustrates a mode profile in the case where a p-type cladding layer is formed to a thickness of 0.25 μm by using AlGaN/GaN supper lattice and an electrode layer as a first electrode layer according to a first embodiment of the present invention is formed to a thickness of 1,500 Å by using Pd thereon to operate as a metal contact layer and a metal waveguide layer, according to the present invention.

### DETAILED DESCRIPTION OF THE INVENTION

The present invention will now be described more fully with reference to the accompanying drawings, in which exemplary embodiments of the invention are shown.

In a semiconductor laser device according to embodiments of the present invention, an electrode layer including a metal waveguide layer, which is formed of a metal having a smaller refractive index than a cladding layer, operates as a waveguide. Thus, the electrode layer operates as a metal contact layer and the waveguide at the same time. Here, the electrode layer may be formed of a metal waveguide layer having a smaller refractive index than a cladding layer, or a multi-layer (two or more layers) including a metal contact layer and a metal waveguide layer.

Semiconductor laser devices according to first and second embodiments of the present invention are examples of a semiconductor laser device. These exemplary semiconductor laser devices do not limit the scope of the present invention.

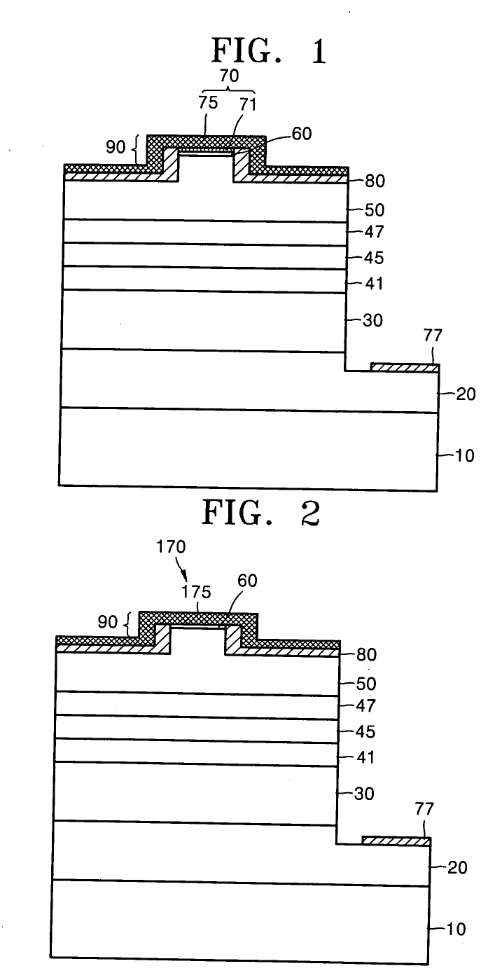

FIG. 1 is a sectional view illustrating the stack structure of a semiconductor laser device according to a first embodiment of the present invention, and FIG. 2 is a sectional view illustrating the stack structure of a semiconductor laser device according to a second embodiment of the present invention.

Referring to FIGS. 1 and 2, a semiconductor laser device according to embodiments of the present invention includes a substrate 10, and a buffer layer 20, a first cladding layer 30, a first waveguide layer 41, an active layer 45, a second waveguide layer 47, and a second cladding layer 50 that are stacked on the substrate 10. An ohmic contact layer 60 may be formed on the second cladding layer 50. In addition, a first electrode layer 70 or 170, for example, a p-type electrode layer is stacked on the ohmic contact layer 60. Here, the first electrode layer 70 or 170 is parallel with the active layer 45 and the second cladding layer 50.

A substrate, a SiC substrate, or a GaN substrate may be mainly used as the substrate 10.

The buffer layer 20 may be formed of a GaN-based group III-V nitride compound semiconductor layer, and used as a contact layer of contacting a second electrode layer 77, for example, an n-type electrode layer that will be described later. For example, the buffer layer 20 may be formed of an n-GaN layer. However, the buffer layer 20 is not limited to a GaN-based layer, but may be formed of another group III-V compound semiconductor layer, which can oscillate the generated laser light.

The first and second cladding layers 30 and 50 may be formed of GaN/AlGaN super lattice layers having a predetermined refractive index; however, the first and second cladding layers 30 and 50 may be formed of other compound semiconductor layers, which can oscillate laser light. For example, the first cladding layer 30 may be formed of an n-AlGaN/n-GaN, n-AlGaN/GaN, or AlGaN/n-GaN semiconductor layer, and the second cladding layer 50 may be formed of a p-AlGaN/p-GaN, p-AlGaN/GaN, or AlGaN/p-GaN semiconductor layer. In addition, the first and second cladding layers 30 and 50 may be formed of an n-AlGaN semiconductor layer and a p-AlGaN semiconductor layer.

The second cladding layer 50 may be formed to a thickness of 1 μm or less.

In the semiconductor laser device according to embodiments of the present invention, the thickness of the second cladding layer 50 may be decreased compared to a cladding layer of a conventional semiconductor laser device that has increased thickness or a large amount of Al to increase an optical confinement factor (OCF). Because the first electrode layer 70 or 170 operates as a waveguide in the semiconductor laser device, a sufficient OCF is obtained.

The first and second waveguide layers 41 and 47 are formed of a material having a higher refractive index than the first and second cladding layers 30 and 50. The first and second waveguide layers 41 and 47 may be formed of a GaN-based group III-V compound semiconductor layer. For example, the first waveguide layer 41 is formed of an n-AlGaN layer, and the second waveguide layer 47 is formed of a p-AlGaN layer.

The active layer 45 may be formed of any material, which can oscillate laser light, preferably a material having small critical current and operation current. The active layer 45 may be formed in any one structure of a multi-quantum well and a single quantum well.

For example, the active layer 45 is formed of any one of GaN, AlGaN, InGaN, and AlInGaN. An electron blocking layer (EBL) (not shown) formed of p-AlGaN may be formed between the active layer 45 and the second waveguide layer 47. The energy gap of the EBL is the largest among the other layer, thus the EBL prevents the transfer of electron to a p-type semiconductor layer.

The second waveguide layer 47, the second cladding layer 50, and the ohmic contact layer 60 are formed on the active layer 45, and a ridge 90 is formed on such semiconductor layers to form a ridge waveguide structure. Hereafter, a method of forming the ridge 90 in the semiconductor laser device according to the present invention will be described.

After forming the buffer layer 20, the first cladding layer 30, the first waveguide layer 41, the active layer 45, the second waveguide layer 47, the second cladding layer 50, and the ohmic contact layer 60, on the substrate 10, a step structure is formed by etching at a portion of the layers to any thickness of the buffer layer 20. Here, the step structure is formed to support a second electrode layer 77, for example, an n-type electrode layer on the buffer layer 20. Thus, the second electrode layer 77 is formed on the exposed portion of the buffer layer 20.

Then, the reminder portion except a portion corresponding to the ridge 90 is etched to any thickness of the second cladding layer 50, or the second cladding layer 50 and the second waveguide layer 47, to expose a portion of the second cladding layer 50. Here, the portion of the second cladding layer 50 that corresponds to the ridge 90 is not etched. A ridge structure and the technology of forming a ridge waveguide structure are well known to the skilled in the art, so that descriptions thereof will be omitted.

The first waveguide layer 41 and the first cladding layer 30 are formed of compound semiconductor layers opposite from the conductive type of the second waveguide layer 47 and the second cladding layer 50. In other words, when the first waveguide layer 41 and the first cladding layer 30 are n-type compound semiconductor layers, the second waveguide layer 47 and the second cladding layer 50 are p-type compound semiconductor layers, for example. Here, the ohmic contact layer 60 may be a p-GaN layer, for example. In other case, when the first waveguide layer 41 and the first cladding layer 30 are p-type compound semiconductor layers, the second waveguide layer 47 and the second cladding layer 50 are n-type compound semiconductor layers, for example. Here, the ohmic contact layer 60 may be, for example, an n-GaN layer. Hereafter, it will be described as an example that the first waveguide 41 and the first cladding layer 30 are n-type compound semiconductor layers and the other layers are the corresponding semiconductor type layers.

A protective layer 80 is formed on the surfaces of the portions of the second cladding layer 50 or the second waveguide layer 47 around the ridge 90 and the sidewalls of the ridge 90. The protective layer 80 is formed of an oxide including at least one of Si, Al, Zr, and Ta.

The first electrode layer 70 or 170 is formed on the ridge waveguide structure 90 on which the protective layer 80 is formed.

The semiconductor laser devices in FIGS. 1 and 2 are formed in a ridge structure; however, the semiconductor laser device according to the present invention may not have a ridge structure.

Referring to FIG. 1, the first electrode layer 70 is formed of a plurality of two layers, e.g., a metal contact layer 71 for an ohmic contact, and a metal waveguide layer 75 formed thereon and functioning as a waveguide. The centeral portion of the metal contact layer 71 contacts the ohmic contact layer 60 on the ridge 90.

The metal waveguide layer 75 is formed of a metal having a smaller refractive index against a luminance wavelength than the cladding layer, more specifically, the second cladding layer 50. For example, the metal waveguide layer 75 is formed of at least any one metal selected from Li, Na, K, Cr, Co, Pd, Cu, Au, Ir, Ni, Pt, Rh, and Ag.

The above metals have refractive indexes against a blue wavelength band, in other words, 400 nm wavelength band, smaller than that of the second cladding layer 50 in the exemplary embodiments.

Here, the refractive index of the metal contact layer 71 is smaller than that of the second cladding layer 50, and the refractive index of the metal waveguide layer 75 is smaller than that of the metal contact layer 71 in this embodiment.

In the semiconductor laser device according to the first embodiment of the present invention, the metal contact layer 71 and the ohmic contact layer 60 operate as a contact, and the metal waveguide layer 75 having a small refractive index operates as a waveguide.

In the semiconductor laser device according to the second embodiment of the present invention, a metal waveguide layer 175 is formed for the first electrode layer 170 to operate as a contact layer and a waveguide at the same time, instead of the first electrode layer 70 in the semiconductor laser device according to the first embodiment of the present invention. Here, the first electrode layer 170, in other words, the metal waveguide layer 175, is formed of a metal having a smaller refractive index than the second cladding layer 50. For example, the first electrode layer 170 is formed of at least any one metal selected from Pd, Ag, Rh, Cu, and Ni.

As described above, the semiconductor laser device according to the present invention includes the metal waveguide layer 75 or 175, which is formed of a metal having a smaller refractive index than the second cladding layer 50 to operate as a waveguide, in the first electrode layer 70 or 170.

Accordingly, the semiconductor laser device according to the present invention can accomplish a sufficient optical confinement effect without increasing the amount of Al in the cladding layer or increasing the thickness of the cladding layer.

In other words, the semiconductor laser device according to exemplary embodiments of the present invention can increase an OCF and reduce the thickness of the second cladding layer 50 located above the active layer 45, by including the metal waveguide layer 75 or 175 operating as a waveguide in the first electrode layer 70 or 170, thus the optical efficiency of laser and the electrical characteristic of the semiconductor laser device may be improved.

In addition, the first electrode layer 70 or 170 operating as a waveguide can reduce the thickness of the second cladding layer 50 and the amount of Al in the second cladding layer 50 required in an optical mode guide. Thus, the operation voltage of the semiconductor laser device may be reduced.

The first electrode layer 70 or 170 can be formed to operate as a waveguide due to the following reasons.

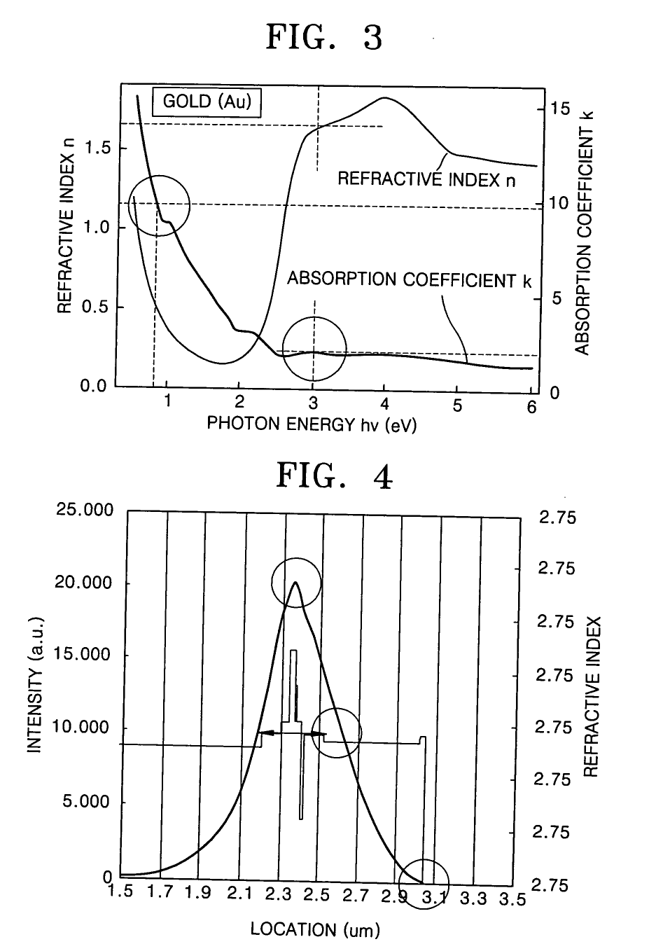

FIG. 3 is a graph illustrating an absorption coefficient and a refractive index of gold (Au) according to photon energy. In the graph of FIG. 3, the photon energy of 0.8 eV corresponds to a wavelength of about 1.55 μm, and the photon energy of 3 eV corresponds to a wavelength of about 400 nm.

As shown in the graph of FIG. 3, a metal has a high absorption coefficient at a long wavelength. Thus, a metal layer cannot operate as a waveguide at a long wavelength.

By considering such absorption characteristic of the metal, a semiconductor laser device is formed that an optical mode is not extended to a metal electrode layer, there by minimizing the combination of the optical mode and the metal layer.

However, a metal has a low absorption coefficient at a short wavelength of about 400 nm as shown in the graph of FIG. 3.

The semiconductor laser device according to the present invention uses such low absorption characteristic of a metal in short wavelength band. Since the optical absorption of a metal is very low at the short wavelength of about 400 nm, an electrode layer formed of a metal can operate as an optical waveguide.

Here, in order for the electrode layer to operate as an optical waveguide, the metal waveguide layer of the electrode layer should be formed of a metal having a smaller refractive index than the cladding layer; more specifically, the cladding layer located between the electrode layer and the active layer, against the wavelength of a laser beam generated from the semiconductor laser device.

Most of metal has a low refractive index than an AlGaN-based material at a short wavelength of 400 nm.

Thus, when the first electrode layer 70 or 170 of the semiconductor laser device according to the present invention is formed to include the metal waveguide layer 75 or 175 by using a metal having sufficiently low absorption coefficient and a refractive index smaller than the second cladding layer 50 at a luminance wavelength of the semiconductor laser device and the first electrode layer 70 or 170 operates as a waveguide by reducing the thickness of the second cladding layer 50, the OCF of the semiconductor laser device according to the present invention is increased. In addition, the waveguide effect of the first electrode layer 70 or 170 may reduce the thickness of the cladding layer and the amount of Al in the cladding layer required in optical mode guide, thus the operation voltage can be reduced.

Furthermore, when the first electrode layer 70 or 170 operates as a waveguide, the symmetry of an optical mode may be greatly improved.

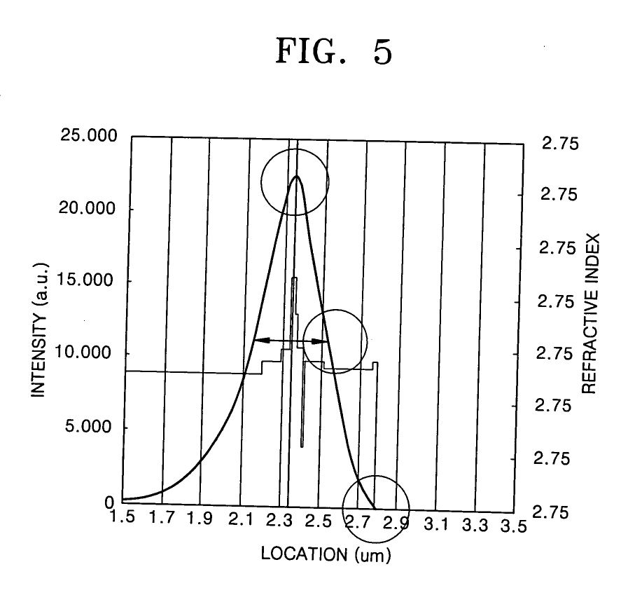

FIG. 4 illustrates a mode profile in the case where a p-type cladding layer is formed to a thickness of 0.5 μm by using AlGaN/GaN supper lattice and an electrode layer is formed to a thickness of 1,500 Å by using Pd thereon as in a conventional semiconductor laser device. FIG. 5 illustrates a mode profile in the case where a p-type cladding layer is formed to a thickness of 0.25 μm by using AlGaN/GaN supper lattice and an electrode layer as the first electrode layer according to the first embodiment of the present invention is formed to a thickness of 1,500 Å by using Pd thereon to operate as a metal contact layer and a metal waveguide layer, according to the present invention.

Since the refractive index of the electrode layer is very much smaller than that of the p-type cladding layer, the refractive indexes of the electrode layers exceed the scales of the graphs of FIGS. 4 and 5, and therefore do not show on the graphs.

The graph of FIG. 4 illustrates an optical mode profile of a conventional semiconductor laser device in which the thickness of the p-type cladding layer is increased to increase an OCF. The graph of FIG. 5 illustrates an optical mode profile of a semiconductor laser device according to the present invention in which the thickness of the p-type cladding layer is reduced by half in comparison with a conventional semiconductor laser device and the electrode layer is formed of any one of Pd, Ag, Rh, Cu, and Ni for operating as the contact layer and the waveguide.

As shown in the graphs of FIGS. 4 and 5, when the thickness of the p-type cladding layer is reduced by half and the electrode layer operates as the waveguide, the OCF of the semiconductor laser device is increased from 2.4% to 2.7%. In other words, the OCF is improved by 12.5%. Here, the OCF corresponds to the calculated overlap coefficient of the optical profile and the active layer, more specifically, a quantum well.

In addition, in comparison with the conventional semiconductor laser device, the problem of cracks during an epitaxial growth may be improved by reducing the thickness of the p-cladding layer by about half and the perpendicular resistance of the device is reduced due to thin thickness, thus the driving voltage, i.e., operation current, can be reduced.

Furthermore, the symmetry of the optical mode can be improved in the semiconductor laser device according to the present invention.

In the graph of FIG. 5, the optical mode profile of the semiconductor laser device according to the present invention in which one electrode layer operates as the metal contact layer and the metal waveguide layer is shown. When the semiconductor laser device according to embodiments of the present invention in which the electrode layer including the metal contact layer and the metal waveguide layer operates as a contact and a waveguide is formed, the semiconductor laser device also improves the OCF and the symmetry of the optical mode, as well as reducing cracks and a resistance due to reducing of the thickness of p-cladding layer.

For example, when an electrode layer of a semiconductor laser device according to the present invention is formed to operate as a waveguide by using Pd and the thickness of a p-type cladding layer is half compared to a conventional semiconductor laser device in which the p-type cladding layer of AlGaN/GaN is formed and an electrode layer of Pd is formed thereon, the semiconductor laser device according to the present invention generates excellent characteristics as the semiconductor laser device having the electrode layer of double-layer. In this case, the OCF is increased while reducing an oscillation current by about 20%. In addition, by reducing the thickness of the p-cladding layer by half, the resistance is reduced by about 30%.

The structure of the semiconductor laser device according to the present invention is not limited to the semiconductor laser devices according to the first and second embodiments of the present invention.

In other words, exclusive of that the first electrode layer 70 or 170, for example, a p-type electrode layer, operates as an optical waveguide and the metal waveguide layer 75 or 175 of the first electrode layer 70 or 170 is formed of a metal having a smaller refractive index than the second cladding layer 50, for example, a p-type cladding layer, located between the active layer 45 and the first electrode layer 70 or 170, the material and the stack structure of semiconductor layers of the semiconductor laser device according to the present invention may vary.

As described above, the semiconductor laser device according to exemplary embodiments of the present invention is formed for the electrode layer to operate as a waveguide, thus the OCF is improved.

Accordingly, the OCF is increased while reducing the thickness of the cladding layer. By increasing the OCF, an oscillation current and an operation current are reduced and the lifespan of the semiconductor laser device is increased while increasing a maximum output.

In addition, the semiconductor laser device according to exemplary embodiments of the present invention can improve the OCF without generating problems in increasing the amount of Al in the cladding layer or the thickness of the cladding layer in a conventional semiconductor laser device.

More specifically, the generation of cracks is reduced by reducing strain, which is applied to the cladding layer during the epitaxial growth, and the deterioration of the active layer is prevented by reducing an exposure period to a high temperature after forming the active layer though reducing the thickness of the cladding layer.

A p-type cladding layer is the main source of the resistance in most of a semiconductor laser device; however, the thickness of the p-type cladding layer is reduced in the semiconductor laser device according to the present invention, thus the resistance is reduced and the operation current is reduced. In addition, the generation of heat due to the joule heat is reduced, thus the operation characteristics at a high temperature and a high output is improved and a modulation operation at a high speed is improved.

Furthermore, the symmetry of the optical mode is improved by reducing the thickness of the cladding layer, thus the symmetry of a far field pattern is improved. Accordingly, spot shapes become symmetrical on a recording surface, resulting in the improvement of an SNR in a system using the semiconductor laser device according to the present invention as a light source.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A semiconductor laser device comprising:
a substrate;
an active layer;
a first cladding layer located between the active layer and the substrate;
a second cladding layer located on a side of the active layer opposite to the first cladding layer; and
a first electrode layer including a metal waveguide layer, which is formed of a metal having a smaller refractive index than the second cladding layer, and formed on the second cladding layer on a side opposite to the active layer, wherein the first electrode layer is formed to operate as a waveguide.

2. The semiconductor laser device of claim 1, wherein the first electrode layer comprising:
the metal waveguide layer; and
a metal contact layer located between the second cladding layer and the metal waveguide layer.

3. The semiconductor laser device of claim 2, wherein the metal waveguide layer is formed of at least any one selected from Li, Na, K, Cr, Co, Pd, Cu, Au, Ir, Ni, Pt, Rh, and Ag.

4. The semiconductor laser device of claim 1, wherein the first electrode layer comprises the metal waveguide layer only, which operates as a contact layer and a waveguide.

5. The semiconductor laser device of claim 4, wherein the metal waveguide layer is formed of at least any one selected from Pd, Ag, Rh, Cu, and Ni.

6. The semiconductor laser device of claim 1, wherein the active layer is formed of any one selected from GaN, AlGaN, InGaN, and AlInGaN, and has any one structure of a multi-quantum well and a single quantum well.

7. The semiconductor laser device of claim 1, wherein the first and second cladding layers are compound semiconductor layers of opposite conductive type and formed of any one of GaN/AlGaN super lattice structure and AlGaN.

8. The semiconductor laser device of claim 1, further comprising a first waveguide layer and a second waveguide layer between the first cladding layer and the active layer and the active layer and the second cladding layer, respectively.

9. The semiconductor laser device of claim 8, wherein the first and second waveguide layers are GaN-based group III-V compound semiconductor layers of opposite conductive type.

10. The semiconductor laser device of claim 9, further comprising a ridge, wherein the ridge is formed by etching to a thickness of the second cladding layer or a thickness of the second cladding layer and the second waveguide layer, in the reminder portion except for a portion corresponding to the ridge.

11. The semiconductor laser device of claim 1, further comprising an ohmic contact layer between the second cladding layer and the first electrode layer.

12. The semiconductor laser device of claim 1, further comprising a ridge, wherein the ridge is formed by etching to any thickness of the second cladding layer in the reminder portion except for a portion corresponding to the ridge.

13. The semiconductor laser device of claim 12, further comprising an ohmic contact layer between the portion of the second cladding layer corresponding to the ridge and the first electrode layer.

14. The semiconductor laser device of claim 13, wherein the ohmic contact layer is any one of an n-GaN layer and a p-GaN layer.

15. The semiconductor laser device of claim 12, further comprising a protective layer covering the surface of the second cladding layer that is exposed by etching to form the ridge and the sidewalls of the ridge.

16. The semiconductor laser device of claim 15, wherein the protective layer is formed of an oxide including at least any one element selected from Si, Al, Zr, and Ta.

17. The semiconductor laser device of claim 1, wherein the substrate is any one selected from a sapphire substrate, an SiC substrate and a GaN substrate.

18. The semiconductor laser device of claim 1, further comprising a buffer layer between the substrate and the first cladding layer.

19. The semiconductor laser device of claim 18, wherein the buffer layer is a GaN-based group III-V nitride compound semiconductor layer.

20. The semiconductor laser device of claim 18, wherein a step structure is formed on the buffer layer, and a second electrode layer is formed on the buffer layer.
